(19) United States
(12) Patent Application Publication
(10) Pub. No.: US 2005/0095808 A1
(43) Pub. Date: May 5, 2005

(54) Thermal oxidation method for topographic feature corner rounding

(75) Inventors: Hsien-Kuang Chiu, Hsin-Chu (TW); Fang-Cheng Chen, Hsin-Chu (TW)

Correspondence Address: TUNG & ASSOCIATES;Suite 120, 838 W. Long Lake Road, Bloomfield Hills, MI, 48302, US

(73) Assignee: Industrial Technology Research Institute

(21) Appl. No.: 10/701,803

(22) Filed: Nov. 4, 2003

(51) Int. Cl. H01L 21/336; H01L 21/8234; H01L 21/76; H01L 21/302

(52) U.S. Cl. 438/425; 438/426; 438/296; 438/197

(57) ABSTRACT

Within a method for forming a topographic feature within a microelectronic substrate employed within a microelectronic fabrication, there is employed an oxidation mask layer sequentially as: (1) an oxidation mask; and then (2) an etch mask, for forming the topographic feature with a rounded corner within the microelectronic substrate. The method is particularly useful for forming within semiconductor substrates isolation trenches with rounded corners, such as to provide for enhanced performance of microelectronic devices formed within active regions adjacent the isolation trenches and isolation regions formed therein.

### BACKGROUND OF THE INVENTION

1. Field of the Invention

The present invention relates generally to methods for forming topographic features within microelectronic substrates. More particularly, the present invention relates to methods for forming, with rounded corners, topographic features within microelectronic substrates.

2. Description of the Related Art

Common in the art of semiconductor fabrication when fabricating semiconductor integrated circuits within semiconductor substrates is the use of isolation regions formed within isolation trenches which in turn define active regions of the semiconductor substrates. Isolation regions formed within isolation trenches generally provide an effective means for electrically isolating various semiconductor devices formed within the active regions of the semiconductor substrates.

While isolation regions formed within isolation trenches are thus clearly desirable in the art of microelectronic fabrication and often essential in the art of microelectronic fabrication, isolation regions formed within isolation trenches are nonetheless not entirely without problems in the art of microelectronic fabrication.

In that regard, as microelectronic integration levels have increased and microelectronic device dimensions have decreased, it has become increasingly difficult in the art of microelectronic fabrication, and in particular in the art of semiconductor integrated circuit microelectronic fabrication, to fabricate isolation trenches and isolation regions with limited detrimental impact to microelectronic devices, and in particular semiconductor devices, formed within active regions adjacent the isolation trenches and isolation regions.

It is thus towards the goal of forming within semiconductor substrates isolation trenches and isolation regions with limited detrimental impact to semiconductor devices formed within active regions adjacent the isolation trenches and isolation regions that the present invention is directed.

Various methods have been disclosed in the art of microelectronic fabrication for forming, with desirable properties, isolation regions within isolation trenches within microelectronic substrates.

Included among the methods, but not limited among the methods, are methods disclosed within Moon et al., in U.S. Pat. No. 5,719,085 (a multiple thermal oxidation method for forming an isolation trench with rounded corners); and (2) Peidous, in U.S. Pat. No. 5,989,978 (an additional multiple thermal oxidation method for forming an isolation trench with rounded corners).

Desirable in the art of microelectronic fabrication are additional methods for forming within microelectronic substrates isolation trenches and isolation regions with limited detrimental. impact to microelectronic devices formed within active regions adjacent the isolation trenches and isolation regions.

It is towards the foregoing object that the present invention is directed.

### SUMMARY OF THE INVENTION

A first object of the present invention is to provide a method for forming an isolation region within an isolation trench within a microelectronic substrate.

A second object of the present invention is to provide a method in accord with the first object of the present invention, wherein the isolation region and the isolation trench are formed with limited detrimental impact to a microelectronic device formed within an active region adjacent the isolation trench and the isolation region.

In accord with the objects of the present invention, there is provided by the present invention a method for fabricating a microelectronic fabrication.

To practice the method of the present invention, there is first provided an oxidizable substrate having formed thereupon an oxidation mask layer which leaves exposed a portion of the oxidizable substrate. There is then oxidized the oxidizable substrate while employing the oxidation mask layer, to form an oxidized substrate having formed therein an oxidized region having an extension extending beneath the oxidation mask layer. There is then etched sequentially the oxidized region and the oxidized substrate, while employing the oxidation mask layer as an etch mask layer, to form an etched oxidized substrate having formed therein a topographic feature.

The invention provides particular value within the context of forming, with a rounded corner, an isolation trench within a semiconductor substrate.

The present invention provides a method for forming an isolation region within an isolation trench within a microelectronic substrate, wherein the isolation region and the isolation trench are formed with limited detrimental impact to a microelectronic device formed within an active region adjacent the isolation trench and the isolation region.

The present invention realizes the foregoing object by first oxidizing an oxidizable substrate while employing an oxidation mask layer to form an oxidized substrate having formed therein an oxidized region having an extension beneath the oxidation mask layer, prior to employing the oxidation mask layer as an etch mask layer for etching the oxidized region and the oxidized substrate to form a topographic feature within the oxidized substrate. The method of the present invention provides that the topographic feature, which may be an isolation trench, is formed with a rounded corner due to the presence of the extension interposed between the oxidized substrate and the oxidation mask layer, such that a microelectronic device formed within an active region adjacent the isolation trench (and an isolation region formed therein) is formed with limited detrimental impact from the isolation trench and the isolation region.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5 and FIG. 6 show a series of schematic cross-sectional diagrams illustrating the results of progressive stages of fabricating, in accord with a preferred embodiment of the present invention, a semiconductor substrate having formed therein an isolation trench having formed therein an isolation region.

### DESCRIPTION OF THE PREFERRED EMBODIMENT

The present invention provides a method for forming an isolation region within an isolation trench within a microelectronic substrate, wherein the isolation region and the isolation trench are formed with limited detrimental impact to a microelectronic device formed within an active region adjacent the isolation trench and the isolation region.

The present invention realizes the foregoing object by first oxidizing an oxidizable substrate while employing an oxidation mask layer to form an oxidized substrate having formed therein an oxidized region having an extension beneath the oxidation mask layer, prior to employing the oxidation mask layer as an etch mask layer for etching the oxidized region and the oxidized substrate to form a topographic feature therein. The method of the present invention provides that the topographic feature, which may be an isolation trench, is formed with a rounded corner due to the presence of the extension interposed between the oxidized substrate and the oxidation mask layer, such that a microelectronic device formed within an active region adjacent the isolation trench (and an isolation region formed therein) is formed with limited detrimental impact from the isolation trench and the isolation region.

While the preferred embodiment of the present invention illustrates the present invention most particularly within the context of forming within a semiconductor substrate an isolation trench with a rounded corner such that there may be formed within an active region of the semiconductor substrate adjacent the isolation trench (and an isolation region formed therein) a semiconductor device with enhanced performance, the present invention is not intended to be so limited.

Rather, the present invention may be employed for forming, with rounded corners, topographic features such as but not limited to trenches and plateaus within microelectronic substrates including but not limited to semiconductor substrates and non-semiconductor substrates, provided that the microelectronic substrates are formed of microelectronic materials subject to thermal oxidation to form interposed between an oxidation mask layer and an oxidized microelectronic substrate an extension. Such microelectronic materials may thus include, but are not limited to, microelectronic conductor materials, microelectronic semiconductor materials and microelectronic dielectric materials.

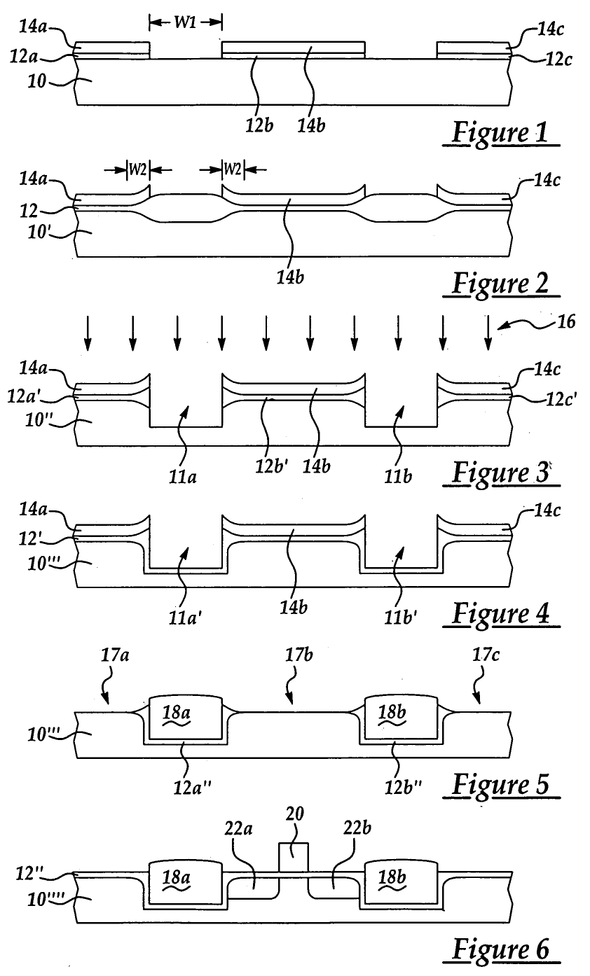

Referring now to FIG. 1 to FIG. 6, there is shown a series of schematic cross-sectional diagrams illustrating the results of progressive stages of fabricating, in accord with a preferred embodiment of the present invention, a semiconductor substrate having formed therein an isolation trench in turn having formed therein an isolation region.

Shown in FIG. 1 is a schematic cross-sectional diagram of the semiconductor substrate at an early stage in its fabrication in accord with the preferred embodiment of the present invention.

Shown in FIG. 1 is a semiconductor substrate 10 having formed thereupon a series of patterned pad oxide layers 12a, 12b and 12c in turn having formed aligned thereupon a series of patterned silicon nitride layers 14a, 14b and 14c, where the series of patterned silicon nitride layers 14a, 14b and 14c serves as a series of patterned oxidation mask layers with respect to the semiconductor substrate 10. As is illustrated within the schematic cross-sectional diagram of FIG. 1, the series of patterned silicon nitride layers 14a, 14b and 14c exposes portions of the semiconductor substrate 10 with a bidirectional (i.e., areal) linewidth W1 of from about 0.3 to about 1.0 microns.

Within the preferred embodiment of the present invention, the semiconductor substrate 10 is formed of a semiconductor material which is susceptible to oxidation to form an oxide layer upon the semiconductor substrate 10. Such semiconductor materials may include, but are not limited to silicon semiconductor materials, germanium semiconductor materials and silicon-germanium alloy semiconductor materials.

Within the preferred embodiment of the present invention, the series of patterned pad oxide layers 12a, 12b and 12c is typically and preferably formed incident to thermal oxidation of the semiconductor substrate 10, such as to typically and preferably form the series of patterned pad oxide layers 12a, 12b and 12c of thickness of from about 30 to about 100 angstroms.

Within the preferred embodiment of the present invention, the series of patterned silicon nitride layers 14a, 14b and 14c may be formed employing any of several methods as are conventional in the art of microelectronic fabrication, such as to form each of the series of patterned silicon nitride layers 14a, 14b and 14c of thickness from about 500 to about 1500 angstroms.

Referring now to FIG. 2, there is shown a schematic cross-sectional diagram illustrating the results of further processing of the semiconductor substrate whose schematic cross-sectional diagram is illustrated in FIG. 1.

As is illustrated within the schematic cross-sectional diagram of FIG. 2, the semiconductor substrate 10 is oxidized to form a thermally oxidized semiconductor substrate 10′ having formed therein a contiguous isolation region (i.e., local oxidation region) and pad oxide layer 12 which incorporates the series of patterned pad oxide layers 12a, 12b and 12c. As is understood by a person skilled in the art, a pair of local oxidation region isolation region portions of the contiguous isolation region and pad oxide layer 12 is formed with a series of bird's beak extensions beneath the series of patterned silicon nitride layers 14a, 14b and 14c. The series of bird's beak extensions is formed of a smoothly curved linewidth W2 from about 50 to about 500 angstroms beneath each of the series of patterned silicon nitride layers 14a, 14b and 14c.

Referring now to FIG. 3, there is shown a schematic cross-sectional diagram illustrating the results of further processing of the semiconductor substrate whose schematic cross-sectional diagram is illustrated in FIG. 2.

As is shown within the schematic cross-sectional diagram of FIG. 3: (1) the local oxidation region isolation region portion of the contiguous isolation region and pad oxide layer 12; and (2) the thermally oxidized semiconductor substrate 10′ are sequentially anisotropically etched, while employing the series of patterned silicon nitride layers 14a, 14b and 14c as a series of etch mask layers, and in conjunction with an etching plasma 16, to form therefrom: (1) a series of patterned bird's beak enhanced pad oxide layers 12a′, 12b′ and 12c′; and (2) a partially etched thermally oxidized semiconductor substrate 10″ having defined therein a pair of isolation trenches 11a and 11b.

Within the preferred embodiment of the present invention, the etching plasma 16 typically and preferably employs a fluorine containing etchant gas composition for etching the contiguous isolation region and pad oxide layer 12 when forming therefrom the series of bird's beak enhanced patterned pad oxide layers 12a′, 12b′ and 12c′; and (2) a chlorine containing etchant gas composition for etching the thermally oxidized semiconductor substrate 10′ when forming the pair of isolation trenches 11a and 11b within the partially etched thermally oxidized semiconductor substrate 10″. Typically and preferably, each of the pair of isolation trenches 11a and 11b is formed to a depth of from greater than about 500 to about 5000 angstroms within the partially etched thermally oxidized semiconductor substrate 10″.

Referring now to FIG. 4, there is shown a schematic cross-sectional diagram illustrating the results of further processing of the semiconductor substrate whose schematic cross-sectional diagram is illustrated in FIG. 3.

As is illustrated in FIG. 4, the partially etched thermally oxidized semiconductor substrate 10″ has been additionally thermally oxidized to form a partially etched twice thermally oxidized semiconductor substrate 10′″ having formed thereupon a contiguous trench liner and pad oxide layer 12′ which incorporates the series of bird's beak enhanced patterned pad oxide layers 12a′, 12b′ and 12c′. Incident to forming the contiguous trench liner and pad oxide layer 12′, a pair of attenuated isolation trenches 11a′ and 11b′ is formed from the pair of isolation trenches 11a and 11b.

Within the preferred embodiment of the present invention, the partially etched thermally oxidized semiconductor substrate 10″ is further thermally oxidized to form the partially etched twice thermally oxidized semiconductor substrate 10′″ incident to thermal annealing at a temperature of from about 900 to about 1100 degrees centigrade for a time period of from about 30 to about 120 minutes. Under such circumstances, the trench liner layer portions of the contiguous trench liner and pad oxide layer 12′ are formed to a thickness of from about 50 to about 500 angstroms.

Referring now to FIG. 5, there is shown a schematic cross-sectional diagram illustrating the results of further processing of the semiconductor substrate whose schematic cross-sectional diagram is illustrated in FIG. 4.

Shown in FIG. 5 is the results of: (1) forming within the pair of attenuated isolation trenches 11a′ and 11b′ a pair of isolation regions 18a and 18b; (2) stripping from the contiguous trench liner and pad oxide layer 12′ the series of patterned silicon nitride layers 14a, 14b and 14c; and (3) stripping from the partially etched twice thermally oxidized semiconductor substrate 10′″ the pad oxide portions of the contiguous trench liner and pad oxide layer 12′ to leave remaining a pair of patterned trench liner layers 12a″ and 12b″ which leave exposed a series of active regions 17a, 17b and 17c of the partially etched twice thermally oxidized semiconductor substrate 10′″.

The foregoing series of process steps may be undertaken employing methods and materials as are otherwise generally conventional in the art of microelectronic fabrication.

For example, the pair of isolation regions 18a and 18b is typically and preferably formed of a silicon oxide material planarized into the pair of attenuated isolation trenches 11a′ and 11b′. In addition, the series of patterned silicon nitride layers 14a, 14b and 14c may be stripped employing an aqueous phosphoric acid etchant solution, and the contiguous trench liner and pad oxide layer 12′ may be etched while employing an aqueous hydrofluoric acid containing etchant solution.

Referring now to FIG. 6, there is shown a schematic cross-sectional diagram illustrating the results of further processing of the semiconductor substrate whose schematic cross-sectional diagram is illustrated in FIG. 5.

As is illustrated in FIG. 6, the partially etched twice thermally oxidized semiconductor substrate 10″″ has been additionally thermally oxidized to form a partially etched three times thermally oxidized semiconductor substrate 10″″ having formed thereupon a contiguous gate dielectric and trench liner layer 12″, where the gate dielectric layer portion of the contiguous gate dielectric and trench liner layer 12″ is formed to a thickness of from about 30 to about 100 angstroms. There is also shown formed with respect to the active region 17b of the partially etched three times thermally oxidized semiconductor substrate 10″″ juxtaposed the gate dielectric layer portion of the contiguous gate dielectric and trench liner layer 12″ a gate electrode 20 and a pair of source/drain regions 22a and 22b, to form within the active region 17b of the partially etched three times thermally oxidized semiconductor substrate 10″″ a field effect transistor (FET) device.

As is understood by a person skilled in the art, the field effect transistor (FET) device formed within the active region 17b of the partially etched three times thermally oxidized semiconductor substrate 10″″ is formed with enhanced performance and limited detrimental impact from the isolation trenches 11a and 11b or the isolation regions 18a and 18b, since the pair of isolation trenches 11a and 11b or attenuated isolation trenches 11a′ and 11b′ is formed rounded corners.

As is understood by a person skilled in the art, the preferred embodiment of the present invention is illustrative of the present invention rather than limiting of the present invention. Revisions and modifications may be made to methods, materials, structures and dimensions employed for fabricating a semiconductor substrate in accord with the preferred embodiment of the present invention, while still fabricating a microelectronic fabrication in accord with the present invention, further in accord with the accompanying claims.

1. A method for forming a topographic feature within a substrate comprising:
providing an oxidizable substrate having formed thereupon an oxidation mask layer which leaves exposed a portion of the oxidizable substrate;
oxidizing the oxidizable substrate while employing the oxidation mask layer, to form an oxidized substrate having formed therein an oxidized region having an extension extending beneath the oxidation mask layer;
etching sequentially the oxidized region and the substrate, while employing the oxidation mask layer as an etch mask layer, to form an etched oxidized substrate having formed therein a topographic feature.

2. The method of claim 1 wherein oxidized region and the oxidized substrate are sequentially anisotropically etched.

3. The method of claim 1 wherein the topographic feature has a rounded corner.

4. The method of claim 1 wherein the extension is formed interposed between the oxidation mask layer and the oxidized substrate.

5. The method of claim 1 wherein the oxidizable substrate is formed from an oxidizable material selected from the group consisting of oxidizable conductor materials, oxidizable semiconductor materials and oxidizable dielectric materials.

6. The method of claim 1 wherein the extension extends for a distance of from about 50 to about 500 angstroms beneath the oxidation mask layer.

7. The method of claim 1 wherein the topographic feature is selected from the group consisting of a trench and a plateau.

8. The method of claim 1 wherein the topographic feature is formed to a depth of from greater than about 500 to about 5000 angstroms within the oxidizable substrate.

9. A method for forming a trench within a semiconductor substrate comprising:
providing an oxidizable semiconductor substrate having formed thereupon an oxidation mask layer which leaves exposed a portion of the oxidizable semiconductor substrate;
oxidizing the oxidizable semiconductor substrate while employing the oxidation mask layer, to form an oxidized semiconductor substrate having formed therein a local oxidation region having a bird's beak extension extending beneath the oxidation mask layer;
etching sequentially the local oxidation region and the semiconductor substrate, while employing the oxidation mask layer as an etch mask layer, to form an etched oxidized semiconductor substrate having formed therein a trench.

10. The method of claim 9 wherein the local oxidation region and the oxidized semiconductor substrate are sequentially anisotropically etched.

11. The method of claim 9 wherein the trench has a rounded corner.

12. The method of claim 9 wherein the extension is formed interposed between the oxidation mask layer and the oxidized semiconductor substrate.

13. The method of claim 9 wherein the oxidizable semiconductor substrate is formed from an oxidizable semiconductor material selected from the group consisting of silicon semiconductor materials, germanium semiconductor materials and silicon-germanium alloy semiconductor materials.

14. The method of claim 9 wherein the bird's beak extension extends for a distance of from about 50 to about 500 angstroms beneath the oxidation mask.

15. The method of claim 9 wherein the trench is an isolation trench.

16. The method of claim 9 wherein the trench is formed to a depth of from greater than about 500 to about 5000 angstroms within the oxidizable semiconductor substrate.

17. The method of claim 15 further comprising forming an isolation region into the isolation trench.

18. The method of claim 9 wherein the trench is formed adjoining an active region of the etched oxidized semiconductor substrate.

19. The method of claim 18 further comprising forming a semiconductor device formed within the active region.

20. The method of claim 19 wherein the semiconductor device is a field effect transistor device.
